(19) United States
(12) Patent Application Publication
(10) Pub. No.: US 2006/0022228 A1
(43) Pub. Date: Feb. 2, 2006

(54) Method of manufacturing silicon nitride film, method of manufacturing semiconductor device, and semiconductor device

(75) Inventors: Takeshi Hoshi, Kanagawa (JP); Tsuyoshi Saito, Kanagawa (JP); Hitoshi Kato, Iwate (JP); Koichi Orito, Iwate (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: Semiconductor Leading Edge Technologies, Inc., Tsukuba-shi (JP); TOKYO ELECTRON LIMITED, Tokyo (JP)

(21) Appl. No.: 11/038,165

(22) Filed: Jan. 21, 2005

(30) Foreign Application Priority Data
Jul. 29, 2004 (JP) 2004-221490

(51) Int. Cl. H01L 29/78; H01L 21/4763

(52) U.S. Cl. 257/288; 438/591; 438/791; 257/640

(57) ABSTRACT

A method of manufacturing a silicon nitride film that forms a silicon nitride film on a surface of a substrate comprises sequentially repeating first through third steps. The first step includes feeding a first gas containing silicon and nitrogen to the surface of the substrate. The second step includes feeding a second gas containing nitrogen to the surface of the substrate. The third step includes feeding a third gas containing hydrogen to the surface of the substrate.

### CROSS-REFERNCE TO ERLATED APPLICATIONS

This Application is based upon and claims the benefit of priority from the prior Japanese Patent Application No. 2004-221490, filed on Jul. 29, 2004; the entire contents of which are incorporated herein by reference.

### BACKGROUND OF THE INVENTION

The invention relates to a method of manufacturing a silicon nitride film and a method of manufacturing a semiconductor device, and more particularly, to a method of manufacturing a silicon nitride film by LP-CVD (Low Pressure-Chemical Vapor Deposition) method, a method of manufacturing a semiconductor device comprising this method, and a semiconductor device.

Silicon nitride film is formed by LP-CVD method for the purpose of forming a sidewall or liner film of a gate electrode of a semiconductor device. However, when silicon raw material such as SiH₂Cl₂, SiCl₄ and Si₂Cl₆, and NH₃ are used for raw material in this case, chlorine contained in the silicon raw material and hydrogen contained in NH₃ remain in the formed film as impurities. This phenomenon is particularly significant in film formation at low temperatures (e.g., 600° C. or less), which causes problems such as the decrease of density and wet etch resistance of the nitride film.

In this respect, a technique for forming a silicon nitride film by atomic layer deposition (ALD) using Si₂Cl₆ and NH₃ has been proposed for the purpose of reducing impurity content while maintaining the Si/N ratio to be constant.

FIG. 19 is a flowchart showing a technique for forming a silicon nitride film investigated by the inventor in the process of reaching the invention.

More specifically, in the case of this method, in a first step 110, silicon raw material gas containing chlorine such as SiH₂Cl₂ and Si₂Cl₆ is introduced onto a silicon wafer in a reaction chamber.

Next, in a second step 120, nitrogen gas is introduced to replace unreacted gas in the reaction chamber. Then, in a third step 130, activated nitrogen raw material gas is introduced into the reaction chamber.

Next, in a fourth step 140, nitrogen gas is introduced to replace unreacted gas in the reaction chamber.

By this technique, it is possible to form a film containing a smaller amount of chlorine impurities as compared to silicon nitride film formed by conventional LPCVD (see, e.g., Japanese Laid-Open Patent Application 2002-343793).

However, a nitride film used for a sidewall or liner film of a gate electrode of a semiconductor device requires a method of forming a nitride film of high film quality and with high coverage at a film formation temperature of 500° C. or less (e.g., film formation temperature of 450° C.) in order to achieve low thermal budget. On the contrary, according to conventional film formation methods, the amount of impurities in the film increases as the film formation temperature decreases, which causes a problem of the degradation of film quality in terms of wet etch resistance and the like.

For example, fabrication of a semiconductor device having metal gate electrodes by the damascene gate process requires a step of cleaning with HF solution after a liner film is formed with silicon nitride film. In the nitride film formed by the conventional technology at a film formation temperature of 500° C. or less, the amount of etching by HF solution is large, which makes it difficult to form an intended structure.

### SUMMARY OF THE INVENTION

According to an aspect of the invention, there is provided a method of manufacturing a silicon nitride film that forms a silicon nitride film on a surface of a substrate comprising sequentially repeating: a first step of feeding a first gas containing silicon and nitrogen to the surface of the substrate; a second step of feeding a second gas containing nitrogen to the surface of the substrate; and a third step of feeding a third gas containing hydrogen to the surface of the substrate

According to other aspect of the invention, there is provided a method of manufacturing a semiconductor device comprising a step of forming a first silicon nitride film on a substrate including a semiconductor layer, the step of forming the first silicon nitride including sequentially repeating: a first step of feeding a first gas containing silicon and nitrogen to the surface of the substrate; a second step of feeding a second gas containing nitrogen to the surface of the substrate; and a third step of feeding a third gas containing hydrogen to the surface of the substrate.

According to other aspect of the invention, there is provided a semiconductor device comprising: a semiconductor layer; a gate insulation film provided on the semiconductor layer; a gate electrode provided on the gate insulation film; and a gate sidewall made of silicon nitride provided on a side surface of the gate electrode and the gate insulation film, a percentage of chlorine content in a portion adjacent to the gate electrode and the gate insulation film being smaller than the percentage of chlorine content in other portions.

According to other aspect of the invention, there is provided a semiconductor device comprising: a semiconductor layer; a gate insulation film provided on the semiconductor layer; a gate electrode provided on the gate insulation film; and a gate sidewall made of silicon nitride provided on a side surface of the gate electrode and the gate insulation film, an etching rate for hydrofluoric acid in a portion adjacent to the gate electrode and the gate insulation film being smaller than the etching rate for hydrofluoric acid in other portions.

According to other aspect of the invention, there is provided a semiconductor device comprising: a semiconductor layer; a first interlayer insulation film provided on the semiconductor layer and comprising a first silicon nitride film, a second silicon nitride film provided on the first silicon nitride film, and a third silicon nitride film provided on the second silicon nitride film, chlorine content in the first and third silicon nitride-films being smaller than chlorine content in the second silicon nitride film; a second interlayer insulation film provided on the first interlayer insulation film and having smaller dielectric constant than silicon nitride; and an electrode penetrating through the second interlayer insulation film and the first interlayer insulation film to the semiconductor layer.

According to other aspect of the invention, there is provided a semiconductor device comprising: a semiconductor layer; a first interlayer insulation film provided on the semiconductor layer and comprising a first silicon nitride film, a second silicon nitride film provided on the first silicon nitride film, and a third silicon nitride film provided on the second silicon nitride film, an etching rate for hydrofluoric acid in the first and third silicon nitride films being smaller than the etching rate for hydrofluoric acid in the second silicon nitride film; a second interlayer insulation film provided on the first interlayer insulation film and having smaller dielectric constant than silicon nitride; and an electrode penetrating through the second interlayer insulation film and the first interlayer insulation film to the-semiconductor layer.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1 is a flowchart of low-temperature nitride film formation by LPCVD method according to an embodiment of the invention;

FIGS. 2A through 2C are schematic views illustrating a process cross-sectional structure of a silicon wafer for the low-temperature nitride film formation by LPCVD method according to an embodiment of the invention;

FIG. 3 is a schematic view illustrating a reaction chamber used in carrying out the low-temperature nitride film formation by LPCVD method according to an embodiment of the invention;

FIG. 4 is a graphical diagram showing total-reflection fluorescent X-ray measurements for chlorine concentration in the silicon nitride film;

FIG. 5 is a graphical diagram showing the result of evaluating the amount of etching for HF solution;

FIGS. 6A through 6C are schematic views illustrating a method of manufacturing a semiconductor device according to an embodiment of the invention;

FIG. 7 is a schematic view illustrating a cross-sectional structure of a semiconductor device fabricated by the manufacturing method of the comparative example;

FIG. 8 is a schematic view illustrating the cross-sectional structure of a relevant part of a semiconductor device manufactured according to the invention;

FIGS. 9A through 9C are process cross-sectional views showing a method of manufacturing a semiconductor device according to an embodiment of the invention;

FIGS. 10A through 10C are process cross-sectional views showing a method of manufacturing a semiconductor device according to an embodiment of the invention;

FIGS. 11A through 11C are process cross-sectional views showing a method of manufacturing a semiconductor device according to an embodiment of the invention;

FIGS. 12A and 12B are process cross-sectional views showing a method of manufacturing a semiconductor device according to an embodiment of the invention;

FIGS. 13A and 13B are process cross-sectional views showing a method of manufacturing a semiconductor device according to an embodiment of the invention;

FIG. 14 is a cross-sectional view showing another specific example of a semiconductor device obtained by the invention;

FIG. 15 is a cross-sectional view showing another specific example of a semiconductor device obtained by the invention;

FIGS. 16A through 16C are process cross-sectional views showing another specific example of a semiconductor device obtained by the invention;

FIG. 17 is a process cross-sectional view showing another specific example of a semiconductor device obtained by the invention;

FIG. 18 is a flowchart showing a variation of a method of manufacturing a silicon nitride film according to the invention; and

FIG. 19 is a flowchart showing a technique for forming a silicon nitride film investigated by the inventor in the process of reaching the invention.

### DETAILED DESCRIPTION

Embodiments of the invention will now be described with reference to the drawings.

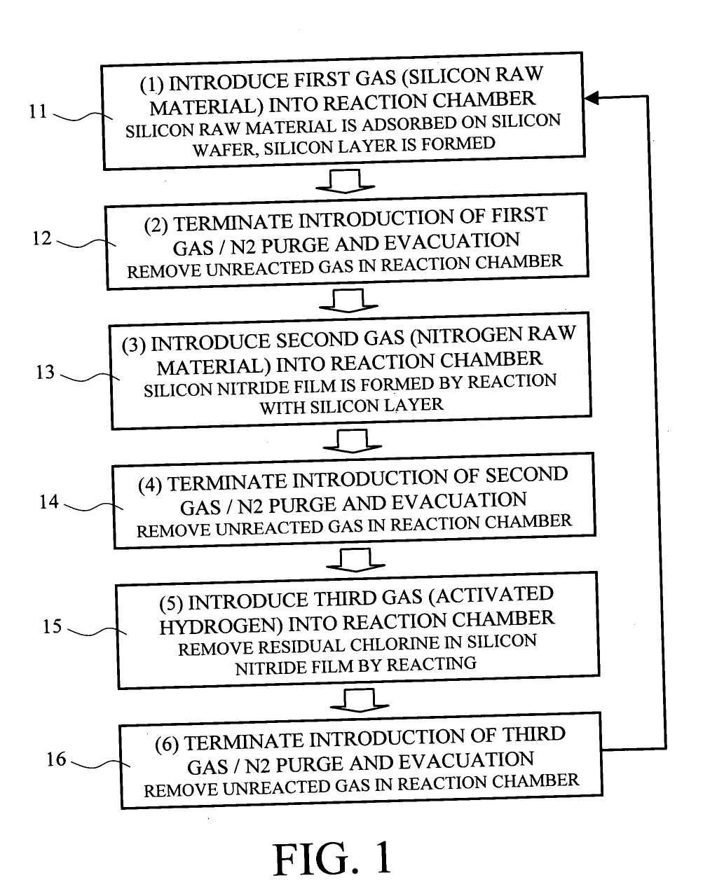

FIG. 1 is a flowchart showing a method of manufacturing a silicon nitride film according to an embodiment of the invention. That is, the present specific example illustrates a method of forming a silicon nitride film by LPCVD method.

First, in a first step 11, raw material gas containing silicon and chlorine is introduced onto a substrate such as a silicon wafer placed in a reaction chamber. Such raw material gas may include, for example, SiH₂Cl₂ and Si₂Cl₆. This raw material gas is hereinafter referred to as “first gas”.

Next, in a second step 12, nitrogen gas is introduced to replace unreacted gas in the reaction chamber.

Next, in a third step 13, raw material gas containing nitrogen is introduced into the reaction chamber. The raw material gas containing nitrogen is hereinafter referred to as “second gas”.

Next, in a fourth step 14, nitrogen gas is introduced to replace unreacted gas in the reaction chamber.

Next, in a fifth step 15, raw material gas containing activated hydrogen is introduced into the reaction chamber. The raw material gas containing activated hydrogen is hereinafter referred to as “third gas”.

Finally, in a sixth step 16, nitrogen gas is introduced to replace unreacted gas in the reaction chamber.

The first to sixth steps described above is grouped into one cycle. A silicon nitride film with low chlorine concentration is formed by repeating this cycle until a desired film thickness is reached. The single cycle may have a duration of about 30 seconds, for example.

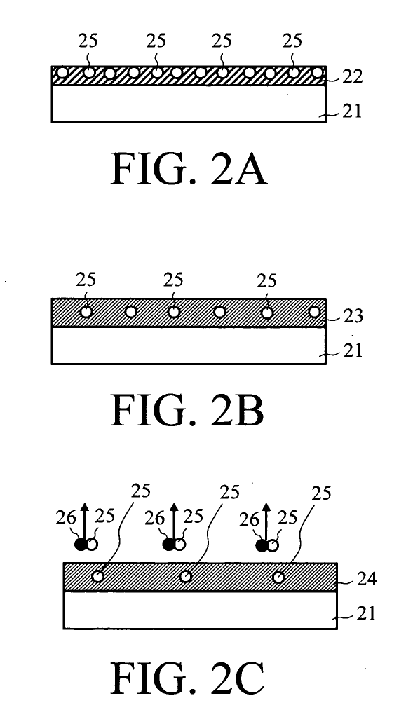

FIGS. 2A through 2C are process cross-sectional diagrams illustrating a method of manufacturing a semiconductor device according to an embodiment of the invention.

FIG. 2A is a schematic view illustrating a cross-sectional structure of the silicon wafer in the first step 11 described above with reference to FIG. 1. More specifically, a layer 22 containing silicon and chlorine 25 is formed on the silicon wafer 21 by introducing the first gas (silicon raw material gas containing chlorine such as SiH₂Cl₂ and Si₂Cl₆) into the reaction chamber.

FIG. 2B is a schematic view illustrating a cross-sectional structure of the silicon wafer in the third step 13 described above with reference to FIG. 1. More specifically, silicon and nitrogen are bonded by introducing the second gas (raw material gas containing nitrogen) into the reaction chamber to form a silicon nitride thin film 23 containing chlorine 25. It should be noted here that nitrogen may be fed in an activated state such as radical or atomic nitrogen to promote bonding between silicon and nitrogen.

FIG. 2C is a schematic view illustrating a cross-sectional structure of the silicon wafer in the fifth step 15 described above with reference to FIG. 1. A silicon nitride thin film 24 with reduced content of chlorine 25 is formed by introducing the third gas (raw material gas containing activated hydrogen) into the reaction chamber. More specifically, by introducing the raw material gas of activated hydrogen, activated hydrogen 26 and residual chlorine 25 form reaction compound, which is removed from the film. As a result, chlorine content in the silicon nitride thin film 23 is reduced.

It should be noted that, for convenience of description, FIG. 2 illustrates the case of forming a silicon nitride film on a planar silicon wafer 21. However, transistors or other structure may have been formed on the surface of the silicon wafer 21. In addition, various substrates such as SOI (semiconductor on insulator) substrates may be used instead of the silicon wafer.

Furthermore, for convenience of description, FIG. 2 shows that a continuous silicon nitride thin film 23 is formed by one cycle of the first to fifth steps. However, the invention is not limited thereto. More specifically, in the invention, a plurality of cycles may be used to form a single-layer silicon nitride thin film. By experiments, the inventor observed that, for example, a single-layer silicon nitride thin film was formed by repeating the set of the first to fifth steps by five cycles.

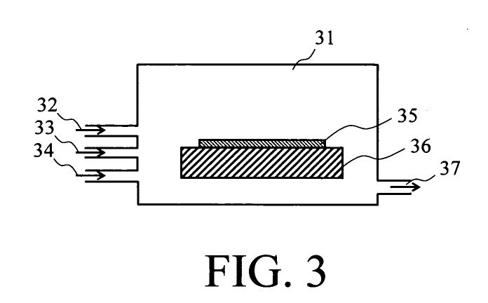

FIG. 3 is a schematic view illustrating a reaction chamber that can be used in a method of manufacturing a silicon nitride film according to an embodiment of the invention. That is, this figure illustrates a reaction chamber of LPCVD apparatus or plasma CVD apparatus.

In the reaction chamber 31, a silicon wafer 35 can be mounted on a wafer stage 36. On the sidewall of the reaction chamber 31, it is provided with an injector 32 for introducing the first gas (raw material gas containing silicon and nitrogen such as SiH₂Cl₂ and Si₂Cl₆), an injector 33 for introducing the second gas (raw material gas containing nitrogen such as NH₃), an injector 34 for introducing the third gas (raw material gas of activated hydrogen), and an exhaust port 37 connected to a vacuum pump.

Activated hydrogen can be generated, for example, by application of a radio frequency wave of 13.56 MHz (megahertz) at 800 W (watt) by a RF generator in a remote plasma generator (not shown). Alternatively, hydrogen can be activated by contacting it with catalyst, or exposing it to ultraviolet radiation. The catalyst may include, for example, tungsten, platinum, palladium, molybdenum, tantalum, titanium, titanium oxide, vanadium, silicon, alumina, silicon carbide, and metallized ceramic. In addition, hydrogen may be activated by utilizing the principle of photocatalysis.

When hydrogen is activated by ultraviolet radiation, it is efficient that the wavelength of ultraviolet radiation is generally 400 nanometers or less.

The hydrogen thus activated is then introduced into the reaction chamber 31.

The second gas containing nitrogen may include, for example, NH₃. Alternatively, gas containing activated nitrogen may be introduced. Also in this case, plasma can be used to activate nitrogen.

Film formation can be carried out in a condition of, for example, a temperature of 450° C., pressure of 130 Pa (pascal), Si₂Cl₆ flow rate of 10 cc, NH₃ flow rate of 1000 cc, and H₂ flow rate of 1000 cc. The duration of flowing these gases may be, for example, about 5, 10, and 20 seconds in this order.

The raw material gas of activated hydrogen may include gas containing hydrogen radicals and atomic hydrogen. For example, when a hydrogen molecule is decomposed by plasma, catalyst or exposure to ultraviolet radiation, a hydrogen atom having an unpaired electron is obtained. This hydrogen atom has high reactivity, and is active.

The second gas containing nitrogen may also include amine-based gas such as hydrazine, except for NH₃.

According to the present embodiment, a silicon nitride film with low chlorine content can be formed at low temperatures by following the steps described above. The film quality of the nitride film is improved by forming the film at low temperatures without applying extra heat to the semiconductor device under the manufacturing process, which results in an effect of improving the reliability of the semiconductor device.

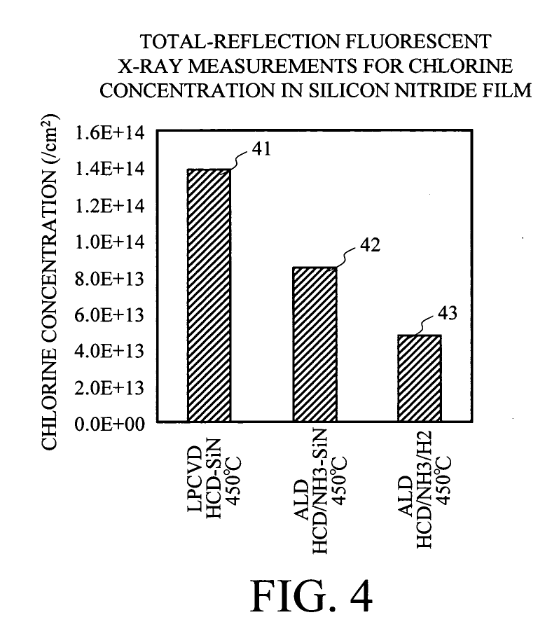

FIG. 4 is a graphical diagram showing chlorine concentration in the silicon nitride film measured by the total-reflection X-ray fluorescence method.

More specifically, comparison was made among three kinds of films: a silicon nitride film 41 of a first comparative example formed by simultaneously introducing two kinds of gas, Si₂Cl₆ and NH₃; a silicon nitride film 42 of a second comparative example formed by alternately introducing the first gas (Si₂Cl₆) and the second gas (activated NH₃) and repeating it; and a silicon nitride film 43 according to the invention formed by introducing the first gas (Si₂Cl₆), the second gas (activated NH₃), and then the third gas (activated hydrogen) and repeating it.

The chlorine concentration measured by the total-reflection X-ray fluorescence method was 1.40×10¹⁴ (cm²) for the silicon nitride film 41 of the first comparative example and 8.60×10¹³ (cm⁻²) for the silicon nitride film 42 of the second comparative example formed by conventional LPCVD, whereas it was 4.7×10¹³ (cm⁻²) for the silicon nitride film 43 formed by the method of the invention. That is, it was found that the invention can reduce the residual amount of chlorine by 65% relative to the silicon nitride film 41 of the first comparative example, and 45% relative to the silicon nitride film 42 of the second comparative example.

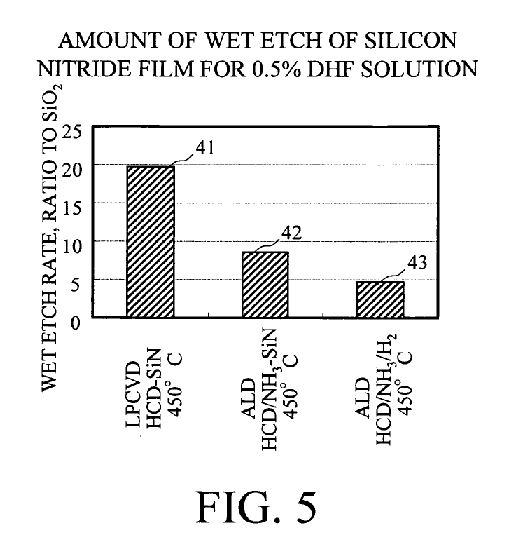

FIG. 5 is a graphical diagram showing the result of evaluating the amount of etching for HF solution. The wet etch rate (its ratio to SiO₂) for 0.5% solution of DHF (dilute hydrofluoric acid) was 19.7 for the silicon nitride film 41 of the first comparative example and 8.5 for the silicon nitride film 42 of the second comparative example formed by conventional LPCVD, whereas it was 4.7 for the silicon nitride film 43 formed by the method of the invention. That is, the invention has enabled the wet etch resistance to be improved by a factor of about 4.2 relative to the silicon nitride film 41 of the first comparative example, and about 1.8 relative to the silicon nitride film 42 of the second comparative example.

As described above, the invention can reduce the amount of chlorine impurities in the silicon nitride film, and improve the wet etch resistance. That is, the invention achieves a silicon nitride film with low thermal budget, constant Si/N ratio, and small amount of impurities, and can improve the film quality such as wet etch resistance by further reducing the amount of chlorine impurities relative to the conventional art.

For example, fabrication of a semiconductor device having metal gate electrodes by the damascene gate process requires a step of cleaning with HF solution after a liner film is formed with nitride film. In the nitride film formed by the conventional technology at a film formation temperature of 500° C. or less, the amount of etching by HF solution is large, which makes it difficult to form an intended structure. On the contrary, according to the invention, a nitride film with good quality having a small amount of etching by HF solution can be formed. As a result, problems associated with the manufacturing process can be avoided, and the electric properties can be improved.

In other words, the invention can achieve reduction of the amount of chlorine impurities in the silicon nitride film, and improve the wet etch resistance, thus providing significant industrial advantages.

Next, a method of manufacturing a semiconductor device comprising the method of manufacturing a silicon nitride film according to the invention will be described.

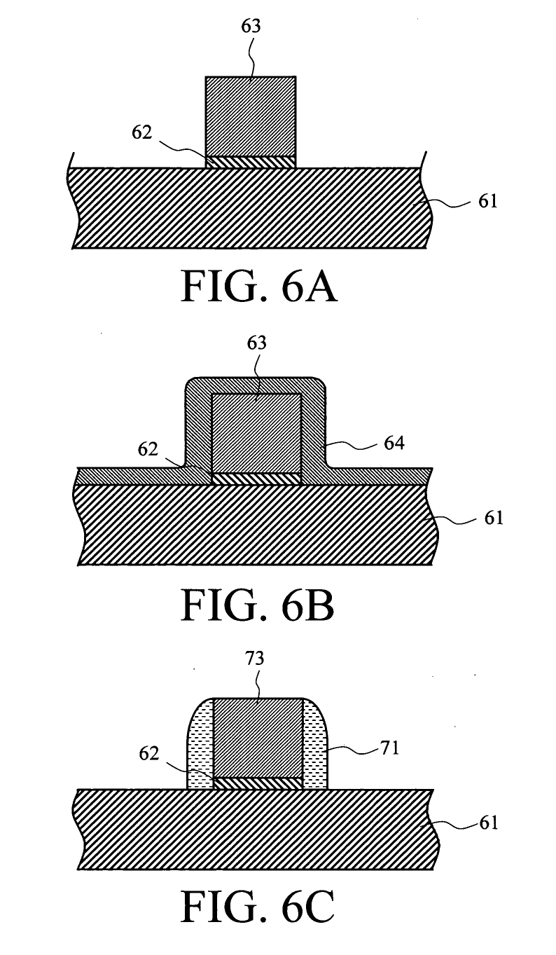

FIGS. 6A through 6C are process cross-sectional views illustrating a method of manufacturing a semiconductor device according to an embodiment of the invention. That is, this specific example shows a process of forming a gate sidewall of a transistor.

First, as shown in FIG. 6A, a gate electrode 63 is formed via a gate isolation film 62 on a silicon substrate 61.

Next, as shown in FIG. 6B, a silicon nitride film 64 is formed thereon. At this time, it is formed by the method according to the invention as described above with reference to FIGS. 1 to 3.

Next, as shown in FIG. 6C, the silicon nitride film 64 is processed by dry etching to form a sidewall 71. More specifically, as a result of etching in a direction generally normal to the principal surface of the silicon substrate 61 by a highly anisotropic etching method such as RIE (reactive ion etching), silicon nitride film is left only on the side surface of the gate isolation film 62 and gate electrode 73 to be formed as sidewall 71. Since this sidewall 71 is formed by the manufacturing method according to the embodiment of the invention, the chlorine concentration in the film is reduced.

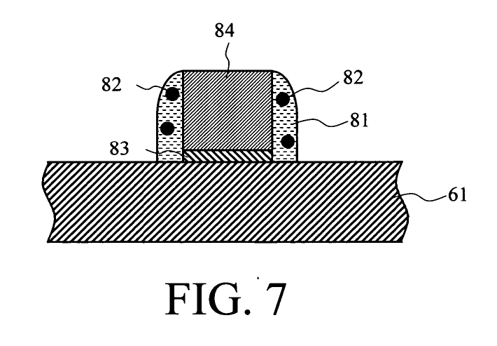

FIG. 7 is a schematic view illustrating a cross-sectional structure of a semiconductor device in which the silicon nitride film of the first or second comparative example described above is provided. More specifically, a gate electrode 84 is provided via a gate insulation film 83 on the silicon substrate 61. The side surface of the gate electrode 84 is covered with a sidewall 81. Since this sidewall 81 is formed by the method of the comparative example using Si₂Cl₆ and NH₃, it has a high concentration of chlorine 82 in the film.

As compared to the sidewall 71 according to the invention, the sidewall 81 of the comparative example has a higher concentration of chlorine 82 in the film. For example, diffusion of chlorine into the gate isolation film 83 or gate electrode 84 may decrease the reliability of the semiconductor device. On the contrary, in the sidewall 71 according to the invention, the amount of residual chlorine content is reduced. As a result, the amount of impurities diffusing into the gate isolation film 62 or gate electrode 73 can be held down, which achieves an effect of improving the reliability of the semiconductor device.

The invention achieves another advantageous effect in that a film of good quality with reduced concentration of chlorine content can be formed at low temperatures also in forming a gate insulation film and liner film (etching stopper film) made of silicon nitride film.

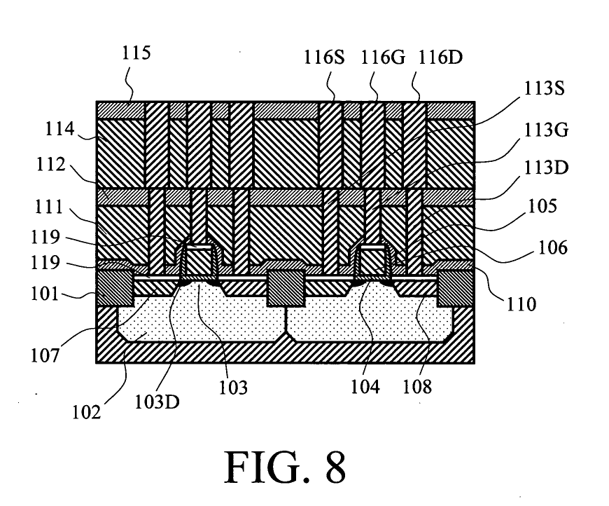

FIG. 8 is a schematic view illustrating the cross-sectional structure of a relevant part of a semiconductor device manufactured according to the invention. More specifically, this figure shows a relevant part of MOSFET (Metal Oxide Semiconductor Field Effect Transistor) that constitutes a semiconductor integrated circuit.

The surface portion of a silicon substrate is isolated and separated by component separation regions 101, and a MOSFET is formed in each of the separated wells 102. Each MOSFET comprises a source region 107, a drain region 108, and a channel 103 provided between them. A gate electrode 106 is provided on the channel 103 via a gate isolation film 104. LDD (lightly doped drain) regions 103D are provided between the source/drain region 107, 108 and the channel 103 for the purpose of preventing the so-called “short channel effect”. A gate sidewall 105 is provided adjacent to the gate electrode 106 on the LDD region 103D. The gate sidewall 105 is provided in order to form the LDD region 103D in a self-aligned manner.

Silicide layers 119 are provided on the source/drain region 107, 108 and the gate electrode 106 for improving contact with the electrodes. The upper side of this structure is covered with a first interlayer isolation film 110, a second interlayer isolation film 111 and a third interlayer isolation film 112, through which contact holes penetrate. Source contact 113S, gate contact 113G, and drain contact 113D are formed through the contact holes. Here, the first interlayer isolation film 110 and the third interlayer isolation film 112 can be formed, for example, from silicon nitride. The second interlayer isolation film 111 can be formed, for example, from silicon oxide.

Further thereon, a fourth interlayer isolation film 114 and a fifth interlayer isolation film 115 are formed. In trenches penetrating through them, source wiring 116S, gate wiring 116G, and drain wiring 116D are each embedded. Here, the fourth interlayer isolation film 114 can be formed from silicon oxide. The fifth interlayer isolation film 115 can be formed from silicon nitride.

In manufacturing a semiconductor device as described above, according to the invention, not only the gate sidewall 105, but also the silicon nitride film constituting the gate insulation film 104, the first interlayer isolation film 110, the third interlayer isolation film 112, and the fifth interlayer isolation film 115 can be formed by the invention described above with reference to FIGS. 1 to 3.

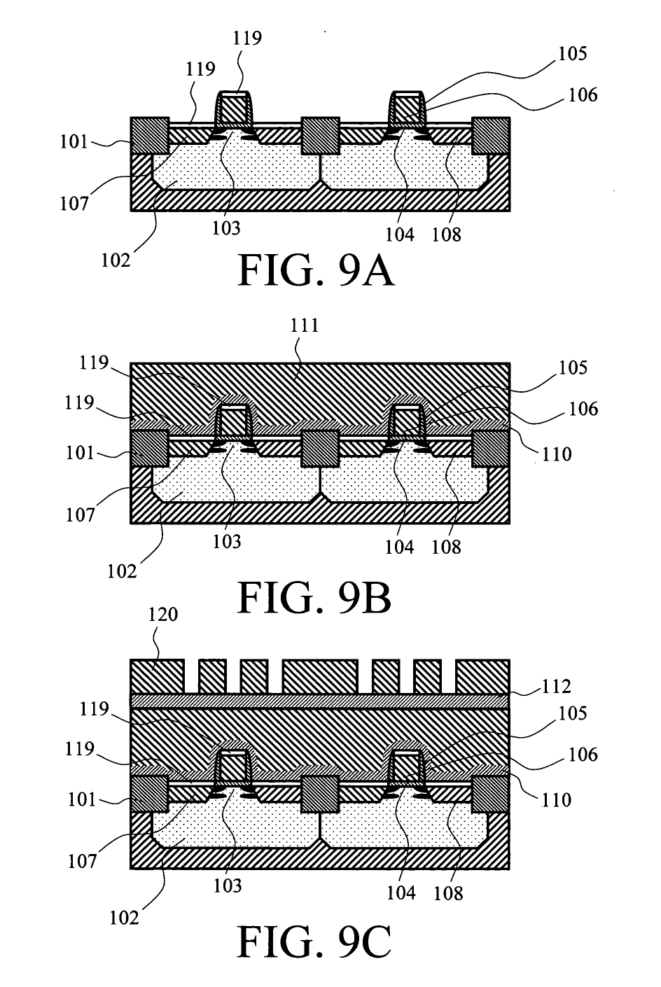

FIGS. 9A to 13B are a process cross-sectional view showing a method of manufacturing a semiconductor device according to an embodiment of the invention.

First, as shown in FIG. 9A, the relevant part of MOS transistor is formed. More specifically, on a Si substrate, a component separation region 101, well 102, channel 103, gate isolation film 104, gate electrode 106, and LDD injection sidewall (gate sidewall) 105 are sequentially formed, and a source region 107 and a drain region 108 are formed. Furthermore, nickel (Ni) sputtering and RTP (rapid thermal processing) are sequentially performed to form a silicide layer 119 made of nickel silicide.

Here, in the step of forming the gate isolation film 104, the silicon nitride film can be formed by the method described above with reference to FIGS. 1 and 2. In this respect, the gate isolation film 104 is not limited to a single silicon nitride film. Rather, it can have a stacked structure of a film made of silicon oxide or high-k (high dielectric constant) material and a silicon nitride film. In this case, the method described above with reference to FIGS. 1 and 2 can be carried out with respect to the silicon nitride film.

In addition, also in the step of forming the gate sidewall 105, as described above with reference to FIG. 6, the method of manufacturing a silicon nitride film according to the invention can be used.

Next, as shown in FIG. 9B, a first interlayer isolation film 110 and a second interlayer isolation film 111 are formed. Here, for the first interlayer isolation film 110, a silicon nitride film with a thickness of about 50 nm is formed by the manufacturing method of the invention as described above with reference to FIGS. 1 to 3. At this time, it is desirable that the temperature during forming the silicon nitride film is kept down at 500° C. or less in order to prevent increase of contact resistance of the underlying silicide layer 119 made of nickel silicide. In this respect, according to the invention, a silicon nitride film with good film quality and reduced chlorine content can be formed even at a lower temperature of about 450° C., for example.

After the silicon nitride film is thus formed as the first interlayer isolation film 110, a silicon oxide film with a thickness of 600 nm is formed as the second interlayer isolation film 111 by plasma CVD using TEOS (tetraethoxysilane) gas at 600° C.

Alternatively, the second interlayer isolation film 111 may be made of material with lower dielectric constant. Such material may include silicon oxides having methyl group(s), silicon oxides having hydrogen group(s), and organic polymers. More specifically, the material may include, for example, various silsesquioxane compounds such as porous methyl silsesquioxane (MSQ), polyimide, fluorocarbon, parylene, and benzocyclobutene. The method of forming such materials may include the spin on glass (SOG) method in which a thin film is formed by spin coating and heat treating the solution.

After the second interlayer isolation film 111 is thus formed, as described in FIG. 9C, a silicon nitride film is formed thereon as the third interlayer isolation film 112. Also at this time, according to the manufacturing method of the invention, a silicon nitride film with a thickness of about 120 nm can be formed at a film formation temperature of about 450° C., for example. By keeping down the film formation temperature, deterioration of nickel silicide constituting the silicide layer 119 can be prevented.

Subsequently, resist is applied and patterned to form a resist pattern 120. The resist pattern 120 is formed, for example, by exposure at 120 nm diameter using an ArF exposure apparatus.

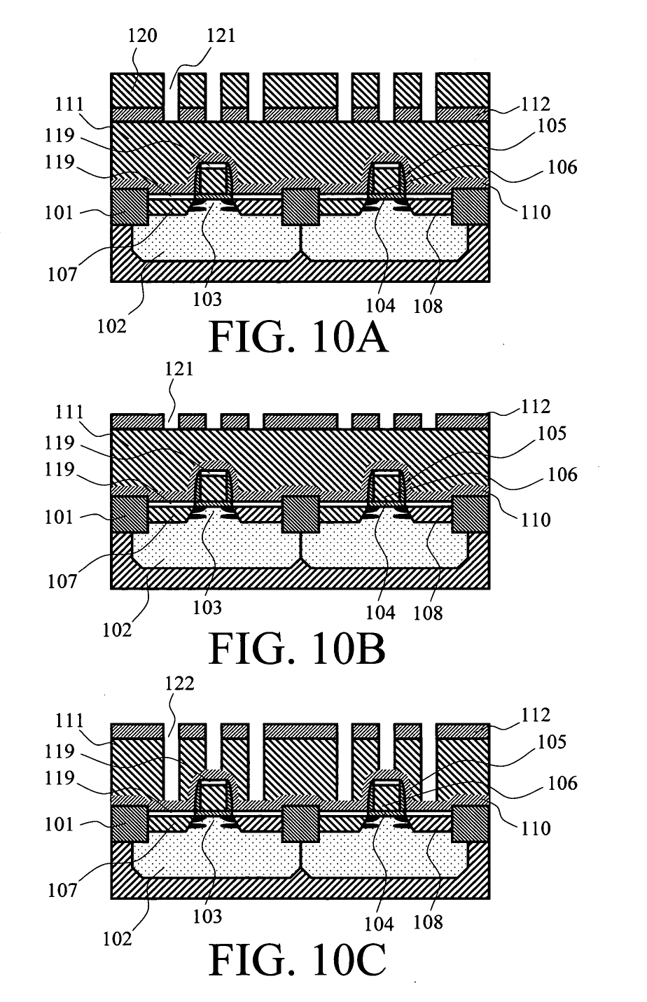

Next, as shown in FIG. 10A, the third interlayer isolation film 112 is etched using the resist pattern 120 as a mask. The etching method may include, for example, a method using ICP (induction coupled plasma) reactive ion etching apparatus. In etching the third interlayer isolation film 112, openings 121 maybe formed in the interlayer isolation film 112, for example, by etching it using mixture gas of CH₂F₂ (50 sccm) and O₂ (50 sccm) at 6.7 pascals (Pa).

Next, as shown in FIG. 10B, the resist mask 120 is removed by ashing with oxygen plasma.

Subsequently, as shown in FIG. 10C, contact holes are formed in the second interlayer isolation film 111. In forming contact holes in the second interlayer isolation film 111, reactive ion etching is carried out using mixture gas of C₄F₆ (50 sccm), CO (50 sccm), O₂ (50 sccm), and Ar (200 sccm) at 6.7 pascals. In this manner, the contact holes 122 in the second interlayer isolation film 111 are formed.

At this time, etching can be stably carried out by using the third interlayer isolation film 112 made of silicon nitride film as an etching mask. More specifically, a large etching selection ratio can be easily obtained by causing etching rates to differ between the silicon oxide film constituting the second interlayer isolation film 111 and the silicon nitride film constituting the third interlayer isolation film 112. Consequently, the second interlayer isolation film 111 can be etched in a condition where it is firmly masked by the third interlayer isolation film 112. That is, a desired opening can be stably formed by eliminating problems such as variation of etching opening size due to mask degradation.

On the other hand, since the first interlayer isolation film 110 is formed from the same silicon nitride film as that of the third interlayer isolation film 112, the first interlayer isolation film 110 functions reliably as an etching stopper. That is, problems due to overetching and underetching can also be eliminated.

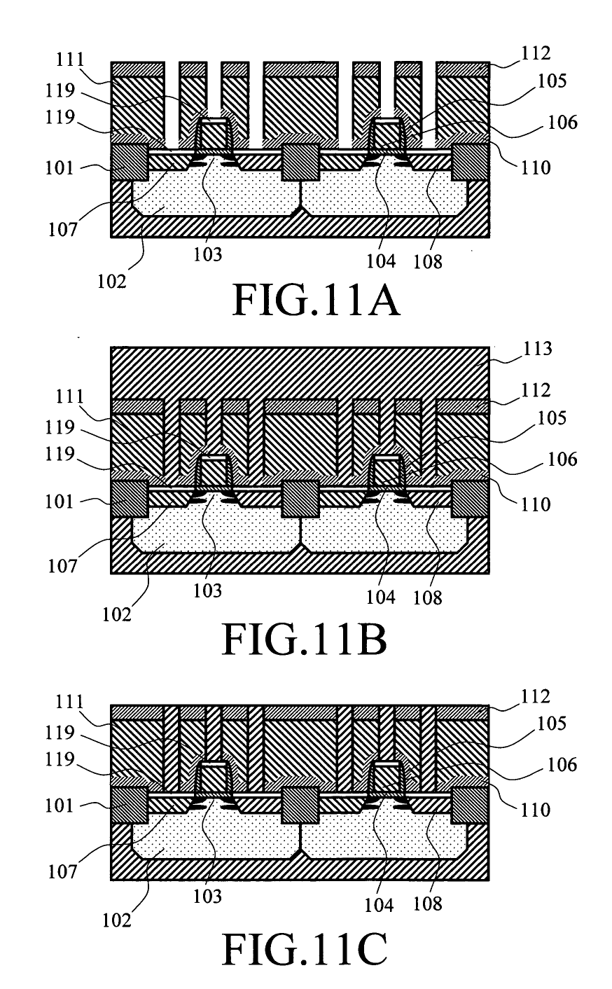

Next, as shown in FIG. 11A, contact holes are formed in the first interlayer isolation film 110. When the first interlayer isolation film 110 is formed from the same kind of materials as that of the third interlayer isolation film 112, the third interlayer isolation film 112 is also etched in this etching step. Consequently, the third interlayer isolation film 112 must be formed with greater thickness than the first interlayer isolation film 110. In terms of the etching condition, etching can be carried out by the reactive ion etching method using mixture gas of CH₂F₂ (50 sccm), O₂ (50 sccm), and Ar (200 sccm) at 6.7 pascals.

Next, as shown in FIG. 11B, contact metal 113 is deposited.

The surface is then polished by chemical mechanical polishing (CMP) for planarization. In this way, a structure in which contact metal is embedded as shown in FIG. 11C can be formed. It should be noted that also at this time, the third interlayer isolation film 112 enables the second interlayer isolation film 111 to be protected against polishing by CMP. More specifically, the second interlayer isolation film 111 can be prevented from being polished and thinned in its film thickness at the time of CMP polishing by providing the third interlayer isolation film 112 made of relatively hard material such as silicon nitride on top of the second interlayer isolation film 111 formed from relatively soft material such as porous silicon oxide. As a result, problems such as increase of interwiring capacitance and current leak can be suppressed.

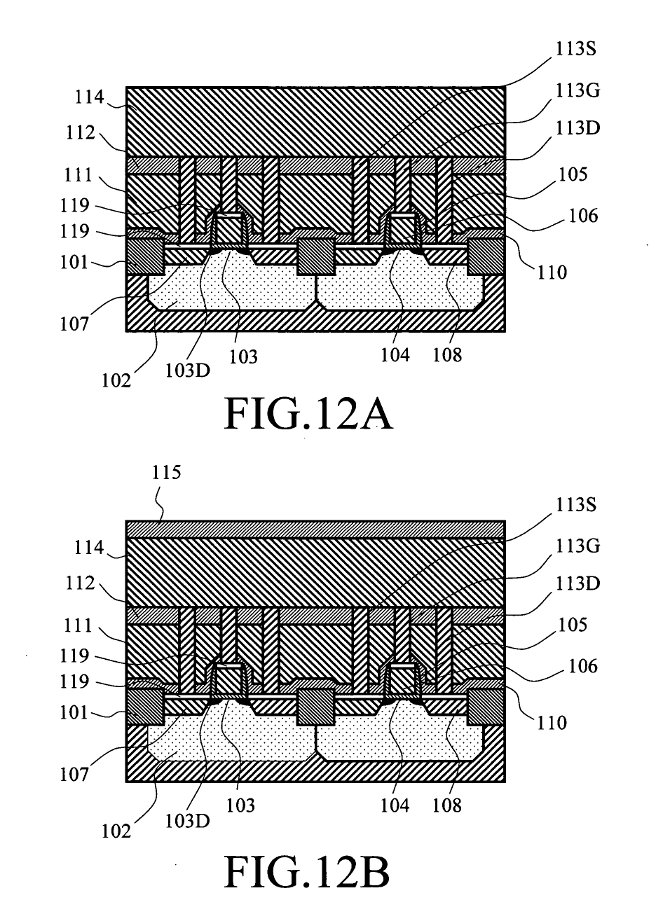

Next, as shown in FIG. 12A, porous silicon oxide is deposited as the fourth interlayer insulation film 114 using raw material such as MSQ. Then, as shown in FIG. 12B, silicon nitride film, for example, is deposited as the fifth interlayer insulation film 115. Also at this time, the manufacturing method of the invention as described above with reference to FIGS. 1 to 3 can be used.

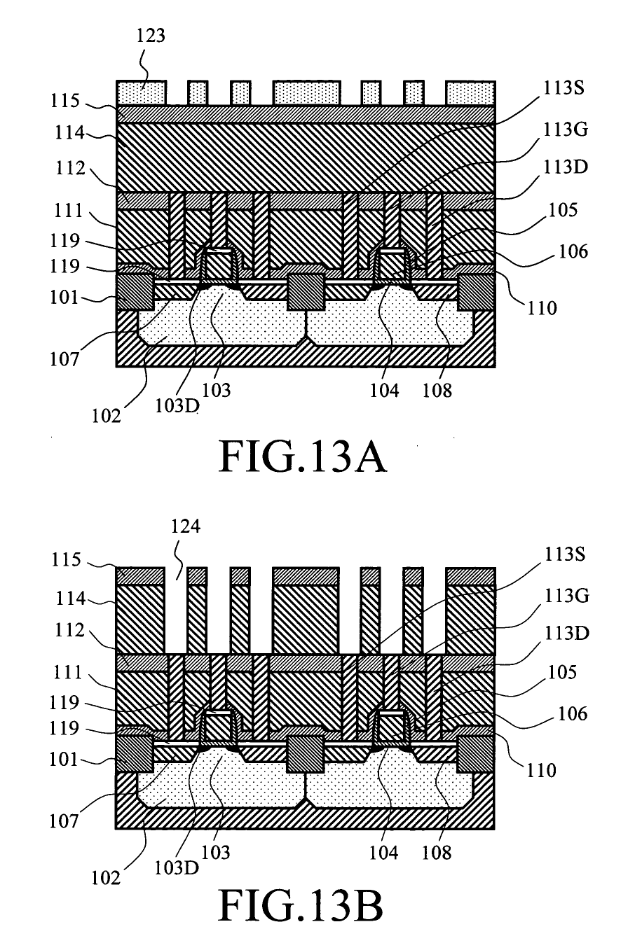

Next, as shown in FIG. 13A, a resist pattern 123 is formed.

Then, as shown in FIG. 13B, trenches 124 are formed by etching the fifth interlayer insulation film 115 and the fourth interlayer insulation film 114, respectively. In etching the fifth interlayer insulation film 115, openings may be formed in the interlayer isolation film 115, for example, by etching it using mixture gas of CH₂F₂ (50 sccm) and O₂ (50 sccm) at 6.7 pascals (Pa). In forming trenches in the fourth interlayer insulation film 114, reactive ion etching may be carried out using mixture gas of C₄F₆ (50 sccm), CO (50 sccm), O₂ (50 sccm), and Ar (200 sccm) at 6.7 pascals. At this time, the fifth interlayer isolation film 115 can be used as a hard mask, and at the same time, the third interlayer isolation film 112 can be used as an etching stopper. More specifically, in etching the fourth interlayer isolation film 114 formed from silicon oxide, the fifth interlayer isolation film 115 formed from silicon nitride can be used as a hard mask, and the third interlayer isolation film 112 also formed from silicon nitride can be used as an etching stopper, to suppress overetching and form the trench with precision.

Subsequently, metal for wiring is deposited, and then smoothing is carried out by CMP polishing. In this way, as shown in FIG. 8, an interlayer wiring structure can be formed in which source wiring 116S, gate wiring 116G, and drain wiring 116D are embedded in the trenches, respectively.

As described above, according to the present embodiment, the silicon nitride film constituting interlayer insulation films 110, 112, and 115 acting as an etching stopper and hard mask can be formed at low temperatures, thereby preventing deterioration of the silicide layer 119. In addition, the silicon nitride film constituting these interlayer insulation films has low concentration of residual chlorine, and thus is superior in terms of the reliability of the semiconductor device.

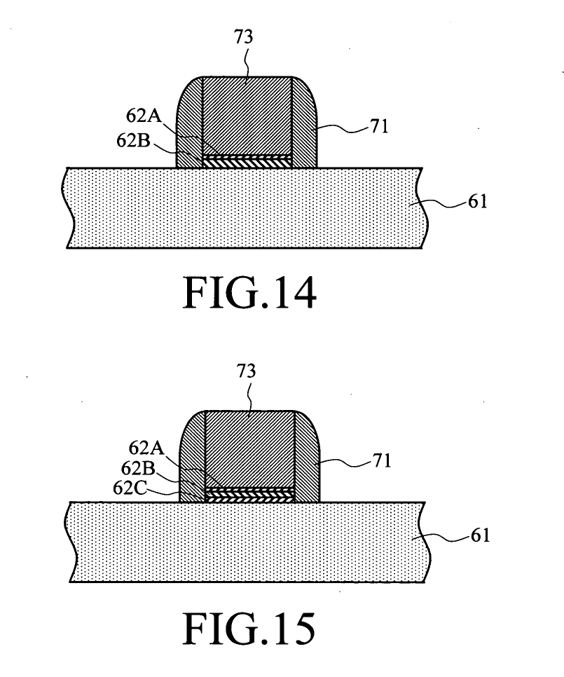

FIG. 14 is a cross-sectional view showing another specific example of a semiconductor device obtained by the invention. That is, this figure shows a gate structure of a semiconductor device, similar to that described above with reference to FIG. 6.

In this specific example, the gate insulation film comprises a first gate insulation film 62A and a second gate insulation film 62B. The first gate insulation film is made of silicon nitride with a thickness of about one nanometer, and is deposited by the method described above with reference to FIGS. 1 to 3. On the other hand, the second gate insulation film is made of high-k (high dielectric constant) material with a thickness of about five nanometers, and is formed by the conventional ALD method.

According to this specific example, the first gate insulation film 62A can prevent impurities such as boron from diffusing out of the gate electrode 73. More specifically, the gate electrode 73 is made of polysilicon and the like doped with impurities such as boron to increase its electric conductivity. On the other hand, in the silicon layer underlying the gate insulation film 62, the impurity concentration must be kept low for forming a channel. However, when the gate insulation film 62 has a smaller thickness, impurities may diffuse from the gate electrode 73 into the channel region of the silicon substrate 61.

In this respect, according to this specific example, the first gate insulation film 62A formed by the method described above with reference to FIGS. 1 to 3 can prevent impurities from diffusing out of the gate electrode 73. More specifically, as described above with reference to FIG. 5, the silicon nitride film formed by the method of the invention has a low etching rate for wet etching, and compact film quality. In addition, the residual chlorine concentration is low. Consequently, it acts as a block layer against diffusion of impurities from the gate electrode 73 into the silicon substrate 61. As a result, diffusion of impurities from the gate electrode is prevented even when the gate insulation film 62 has a smaller thickness, and thus a high-performance transistor can be realized.

FIG. 15 is across-sectional view showing another specific example of a semiconductor device obtained by the invention. More specifically, also in this specific example, a silicon nitride film formed by the method described above with reference to FIGS. 1 to 3 is provided as a first gate insulation film 62A. In addition, in this specific example, a third gate insulation film 62C is provided under a second gate insulation film 62B made of high-k material. The third gate insulation film 62C is made of silicon oxide, for example, and serves to improve adhesion and affinity between the silicon substrate 61 and the second gate insulation film 62B.

Also in this specific example, the first gate insulation film 62A made of silicon nitride film formed by the method described above with reference to FIGS. 1 to 3 can prevent impurities from diffusing out of the gate electrode 73 into the silicon substrate 61, and thus maintain the performance of the transistor.

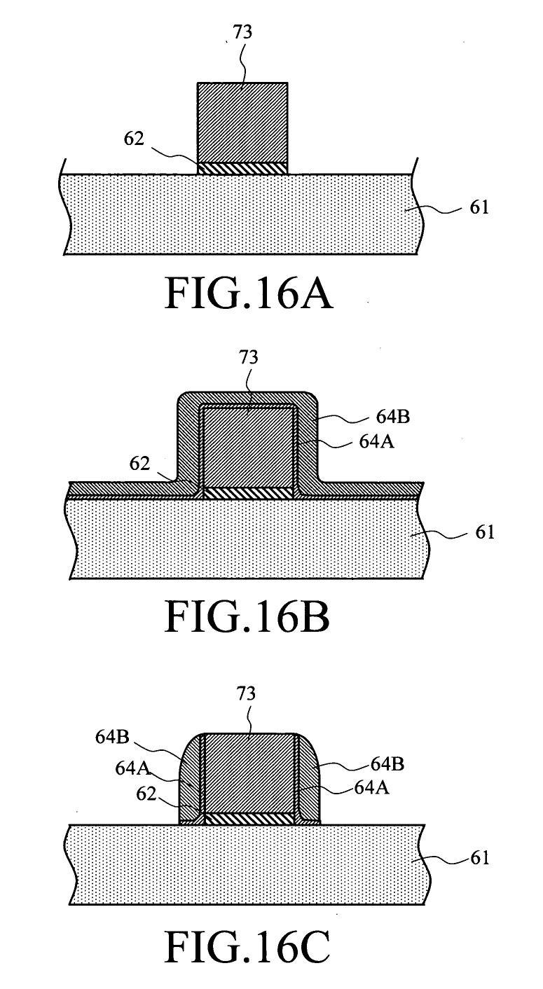

FIGS. 16A through 16C are process cross-sectional views showing another specific example of a semiconductor device obtained by the invention. That is, this specific example shows a process of manufacturing a gate sidewall.

Also in this specific example, in a manner similar to that described above with reference to FIG. 6, a gate electrode 73 is first formed via a gate isolation film 62 on a silicon substrate 61. It should be noted here that, as described above with reference to FIG. 14 or 15, the silicon nitride film obtained by the method described above with reference to FIGS. 1 to 3 may be interposed as part of the gate insulation film 62.

Next, as shown in FIG. 16B, a first silicon nitride film 64A and a second silicon nitride film 64B are formed thereon in this order. At this time, the first silicon nitride film 64A is formed by the method described above with reference to FIGS. 1 to 3. The second silicon nitride film 64B can be formed by the method of the first or second comparative example described above with reference to FIG. 4. The first silicon nitride film 64A may have a film thickness of about 10 nanometers, for example. The second silicon nitride film 64B may have a film thickness of about 40 to 60 nanometers, for example.

Next, as shown in FIG. 16C, the silicon nitride films 64A and 64B are etched back by dry etching to form a sidewall. More specifically, as a result of etching in a direction generally normal to the principal surface of the silicon substrate 61 by a highly anisotropic etching method such as RIE (reactive ion etching), silicon nitride film is left only on the side surface of the gate isolation film 62 and gate electrode 73 to be formed as sidewall. At this time, the first silicon nitride film 64A formed by the method of the invention is formed adjacent to the silicon substrate 61, gate insulation film 62, and gate electrode 73. That is, as described above with reference to FIG. 6, the formed silicon nitride film 64A has low residual chlorine in the film, low etching rate, and compact film quality. Since the second silicon nitride film 64B formed thereon is formed by the method of the first or second comparative example, it has high chlorine content. In addition, the second silicon nitride film 64B according to the method of these comparative examples has a high etching rate and is less compact.

On the contrary, the underlying first silicon nitride film 64A, which has low chlorine content and is compact, can prevent diffusion of chlorine into the substrate 61 and gate insulation film 62, and diffusion of other impurities. In addition, the manufacturing time can be reduced by forming the second silicon nitride film 64B by the method of the first or second comparative example. That is, when the method of the first comparative example is used, silicon nitride film can be deposited at a rate 10 or more times faster than in the method of the invention. The deposition rate of silicon nitride film in the method of the invention is about 0.9 angstrom per minute, for example, while the deposition rate of silicon nitride film in the method of the second comparative example as illustrated in FIG. 15 can be as high as about 2.4 angstrom per minute, for example.

In other words, according to the structure shown in FIG. 16, the manufacturing time can be reduced, and it is possible to realize a gate sidewall that can prevent diffusion of chlorine or other impurities.

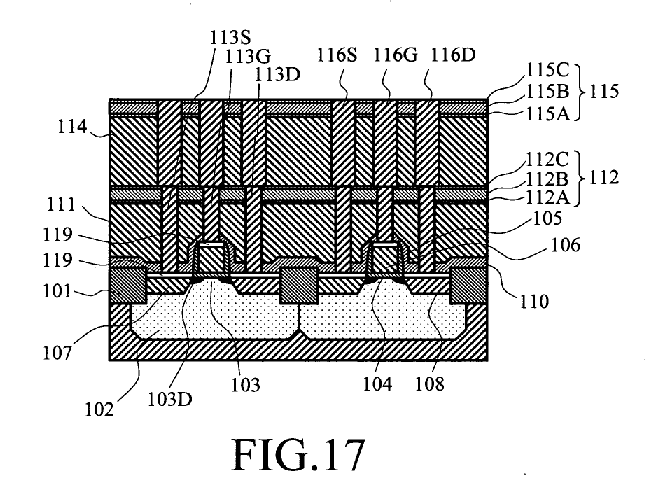

FIG. 17 is a process cross-sectional view showing another specific example of a semiconductor device obtained by the invention. That is, this figure shows a structure similar to the semiconductor device described above with reference to FIG. 8. In FIG. 17, elements similar to those described with reference to FIGS. 8 to 13 are marked with the same numerals and are not described in detail.

In this specific example, the third interlayer insulation film 112 and the fifth interlayer insulation film 115 have three-layer stacked structure, respectively. More specifically, the third interlayer insulation film 112 comprises a first silicon nitride film 112A, a second silicon nitride film 112B, and a third silicon nitride film 112C. Similarly, the fifth interlayer insulation film 115 comprises a first silicon nitride film 115A, a second silicon nitride film 115B, and a third silicon nitride film 115C. In these stacked structures, the first and third silicon nitride films 112A, 112C, 115A, and 115C are formed by the method of the invention described above with reference to FIGS. 1 to 3. On the other hand, the second silicon nitride films 112B and 115B are formed by the method of the first or second comparative example described above with reference to FIG. 4.

According to this specific example, the first and third silicon nitride films 112A, 112C, 115A, and 115C located on the upper and lower sides of the interlayer insulation films 112 and 115 have low residual chlorine, and the etching rate for them can be reduced. That is, they can be used as an etching stopper, and at the same time, they can prevent diffusion of chlorine or other impurities to the surroundings.

Furthermore, the second silicon nitride films 112B and 115B can be formed by the method of the first or second comparative example to reduce the manufacturing time as described above with reference to FIG. 16. For example, the first and third silicon nitride films 112A, 112C, 115A, and 115C can have a thickness of about 10 nanometers, and the second silicon nitride films 112B and 115B can have a thickness of about 100 nanometers. This can significantly reduce the manufacturing time while maintaining the effect of etching stopper and chlorine diffusion prevention.

In addition, such a three-layer structure can also be used for the first interlayer insulation film 110, for example. More specifically, the first interlayer insulation film 110 may have a three-layer structure, in which the upper and lower layer may be a silicon nitride film formed by the method of the invention, and the middle layer may be a silicon nitride film formed by the method of the comparative example. This can significantly reduce the manufacturing time while maintaining the effect of etching stopper and chlorine diffusion prevention.

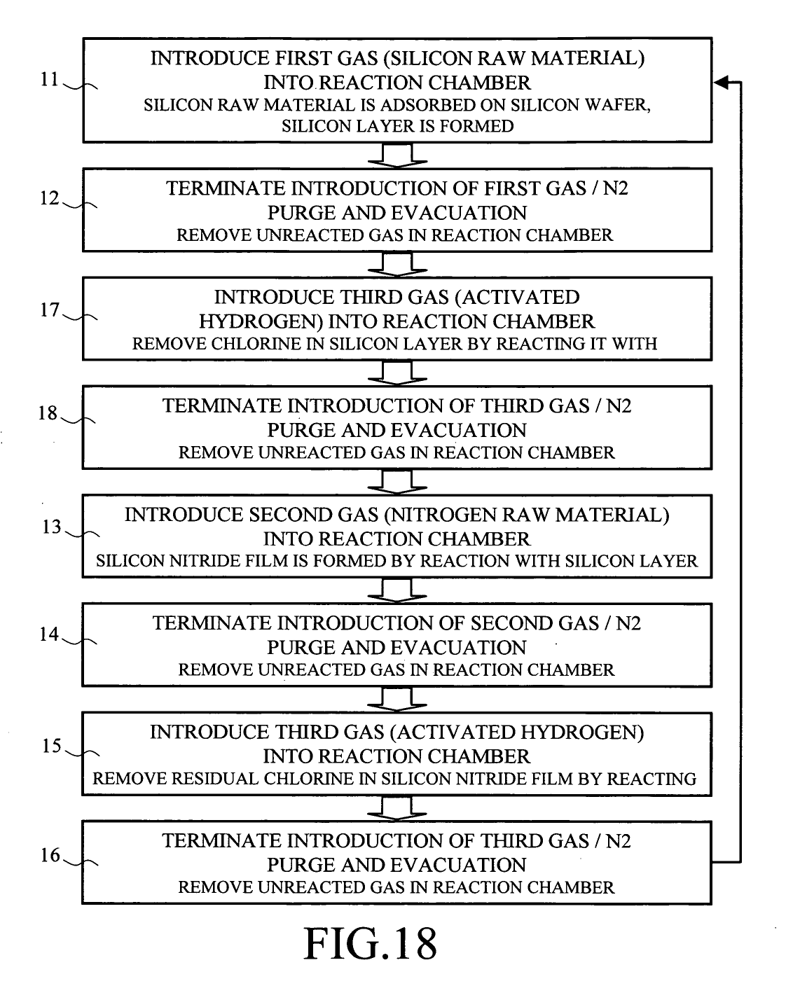

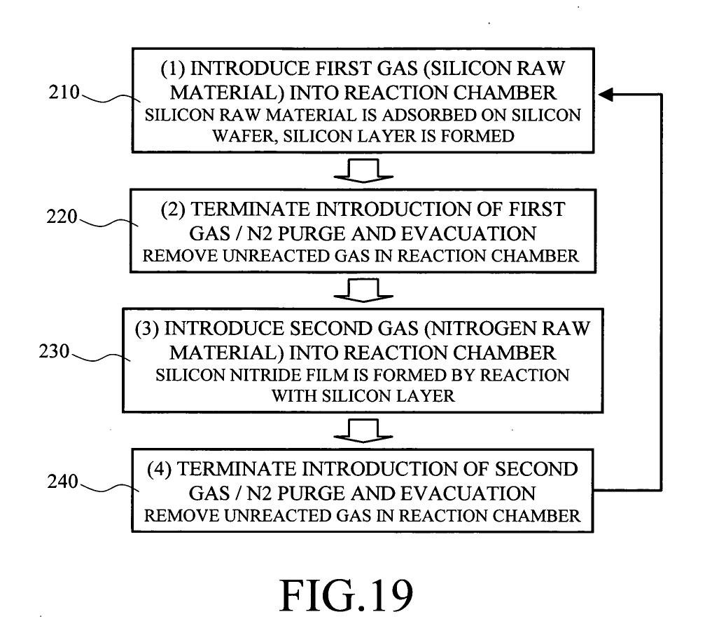

FIG. 18 is a flowchart showing a variation of a method of manufacturing a silicon nitride film according to the invention.

More specifically, this variation begins with step 11 in which the first gas is introduced. In step 12, purge with nitrogen gas is carried out. Subsequently, in step 17, activated hydrogen is introduced as the third gas. Then chlorine contained in the silicon layer formed on the substrate reacts with activated hydrogen and is removed from the silicon layer.

Subsequently, in step 18, purge with nitrogen gas is carried out. Then in step 13, raw material gas containing nitrogen such as ammonia is introduced as the second gas. The subsequent steps are carried out in a similar manner to those shown in FIG. 1.

According to this variation, after the first gas is introduced to form a silicon layer, activated hydrogen is introduced as the third gas (step 17) to abstract chlorine contained in the silicon layer. Furthermore, after the second gas is introduced to form a silicon nitride film, activated hydrogen is introduced (step 15) to abstract chlorine contained in the silicon nitride layer. In this way, residual chlorine is abstracted by activated hydrogen in each state of being a silicon layer and silicon nitride layer. As a result, the concentration of chlorine in the film can be further reduced.

The embodiments of the invention have been described with reference to specific examples.

However, the invention is not limited to these specific examples. For example, any element constituting the semiconductor device manufactured using the manufacturing method of the invention, even if the element is appropriately modified by those skilled in the art, is encompassed within the scope of the invention, as long as it comprises the feature of the invention.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A method of manufacturing a silicon nitride film that forms a silicon nitride film on a surface of a substrate comprising sequentially repeating:
a first step of feeding a first gas containing silicon and nitrogen to the surface of the substrate;
a second step of feeding a second gas containing nitrogen to the surface of the substrate; and
a third step of feeding a third gas containing hydrogen to the surface of the substrate.

2. The method of manufacturing a silicon nitride film as claimed in claim 1, wherein the hydrogen is activated and fed.

3. The method of manufacturing a silicon nitride film as claimed in claim 2, wherein the activation is effected by plasma.

4. The method of manufacturing a silicon nitride film as claimed in claim 2, wherein the activation is effected by at least one of catalyst and ultraviolet radiation.

5. The method of manufacturing a silicon nitride film as claimed in claim 1, wherein the hydrogen is activated to at least one of atomic or radical hydrogen and fed.

6. The method of manufacturing a silicon nitride film as claimed in claim 1, wherein the nitrogen is activated and fed.

7. The method of manufacturing a silicon nitride film as claimed in claim 5, wherein the activation is effected by plasma.

8. The method of manufacturing a silicon nitride film as claimed in claim 6, wherein the activation is effected by at least one of catalyst and ultraviolet radiation.

9. The method of manufacturing a silicon nitride film as claimed in claim 1, further comprising the steps of:
between the first step and the second step, removing the first gas from the surface of the substrate; and
between the second step and the third step, removing the second gas from the surface of the substrate.

10. A method of manufacturing a semiconductor device comprising a step of forming a first silicon nitride film on a substrate including a semiconductor layer,
the step of forming the first silicon nitride including sequentially repeating:
a first step of feeding a first gas containing silicon and nitrogen to the surface of the substrate;
a second step of feeding a second gas containing nitrogen to the surface of the substrate; and
a third step of feeding a third gas containing hydrogen to the surface of the substrate.

11. The method of manufacturing a semiconductor device as claimed in claim 10, further comprising the step of forming a gate electrode on the first silicon nitride film.

12. The method of manufacturing a semiconductor device as claimed in claim 11, further comprising the step of, before the step of forming the first silicon nitride film, forming an insulation film having higher dielectric constant than the first silicon nitride film on the substrate.

13. The method of manufacturing a semiconductor device as claimed in claim 10, wherein
the substrate comprises the semiconductor layer, a gate insulation film selectively provided on a principal surface of the semiconductor layer, and a gate electrode provided on the gate insulation film,
the method further comprising the step of, after the step of forming the first silicon nitride film, removing the first silicon nitride film on the semiconductor layer and the gate electrode by etching the first silicon nitride film in a direction generally normal to the principal surface of the semiconductor layer to leave a sidewall made of the first silicon nitride film on a side surface of the gate insulation film and the gate electrode.

14. The method of manufacturing a semiconductor device as claimed in claim 10, wherein
the substrate comprises the semiconductor layer, a gate insulation film selectively provided on a principal surface of the semiconductor layer, and a gate electrode provided on the gate insulation film,
the method further comprising the steps of:
after the step of forming the first silicon nitride film, forming a second silicon nitride film by a deposition method with a deposition rate greater than the deposition rate for the first silicon nitride film in the step of forming the first silicon nitride film; and
removing the second and first silicon nitride films on the semiconductor layer and the gate electrode by etching the second and first silicon nitride films in a direction generally normal to the principal surface of the semiconductor layer to leave a sidewall made of the second and first silicon nitride films on a side surface of the gate insulation film and the gate electrode.

15. The method of manufacturing a semiconductor device as claimed in claim 10, further comprising the steps of:
forming an interlayer insulation layer on the first silicon nitride film;
forming a layer having one or more openings on the interlayer insulation layer; and
etching the interlayer insulation layer via the one or more openings in a condition that an etching rate for the interlayer insulation layer is greater than the etching rate for the first silicon nitride film.

16. The method of manufacturing a semiconductor device as claimed in claim 10, further comprising the steps of:
forming a second silicon nitride film on the first silicon nitride film by a deposition method with a deposition rate greater than the deposition rate for the first silicon nitride film in the step of forming the first silicon nitride film;
forming a third silicon nitride film on the second silicon nitride film by a method including sequentially repeating:
a fourth step of feeding a first gas containing silicon and nitrogen to the surface of the second silicon nitride film;
a fifth step of feeding a second gas containing nitrogen to the surface of the second silicon nitride film; and
a sixth step of feeding a third gas containing hydrogen to the surface of the second silicon nitride film;
forming an interlayer insulation layer on the third silicon nitride film;
forming a layer having one or more openings on the interlayer insulation layer; and
etching the interlayer insulation layer via the one or more openings in a condition that an etching rate for the interlayer insulation layer is greater than the etching rate for the third silicon nitride film.

17. A semiconductor device comprising:
a semiconductor layer;
a gate insulation film provided on the semiconductor layer;
a gate electrode provided on the gate insulation film; and
a gate sidewall made of silicon nitride provided on a side surface of the gate electrode and the gate insulation film, a percentage of chlorine content in a portion adjacent to the gate electrode and the gate insulation film being smaller than the percentage of chlorine content in other portions.

18. A semiconductor device comprising:
a semiconductor layer;
a gate insulation film provided on the semiconductor layer;
a gate electrode provided on the gate insulation film; and
a gate sidewall made of silicon nitride provided on a side surface of the gate electrode and the gate insulation film, an etching rate for hydrofluoric acid in a portion adjacent to the gate electrode and the gate insulation film being smaller than the etching rate for hydrofluoric acid in other portions.

19. A semiconductor device comprising:
a semiconductor layer;
a first interlayer insulation film provided on the semiconductor layer and comprising a first silicon nitride film, a second silicon nitride film provided on the first silicon nitride film, and a third silicon nitride film provided on the second silicon nitride film, chlorine content in the first and third silicon nitride films being smaller than chlorine content in the second silicon nitride film;
a second interlayer insulation film provided on the first interlayer insulation film and having smaller dielectric constant than silicon nitride; and
an electrode penetrating through the second interlayer insulation film and the first interlayer insulation film to the semiconductor layer.

20. A semiconductor device comprising:
a semiconductor layer;
a first interlayer insulation film provided on the semiconductor layer and comprising a first silicon nitride film, a second silicon nitride film provided on the first silicon nitride film, and a third silicon nitride film provided on the second silicon nitride film, an etching rate for hydrofluoric acid in the first and third silicon nitride films being smaller than the etching rate for hydrofluoric acid in the second silicon nitride film;
a second interlayer insulation film provided on the first interlayer insulation film and having smaller dielectric constant than silicon nitride; and
an electrode penetrating through the second interlayer insulation film and the first interlayer insulation film to the semiconductor layer.
